(19) United States
(12) Patent Application Publication
(10) Pub. No.: US 2026/0353917 A1
(43) Pub. Date: Nov. 5, 2026

(54) LIGHT-EMITTING ELEMENT

(71) Applicant: TAIZHOU GUANYU TECHNOLOGY CO., LTD., ZHEJIANG PROVINCE (CN)

(72) Inventors: HSUPING CHEN, TAINAN CITY (TW); KUO-CHENG HSU, TAICHUNG CITY (TW); QIONG DING, ZHEJIANG PROVINCE (CN)

(21) Appl. No.: 19/655,728

(22) Filed: Apr. 23, 2026

(30) Foreign Application Priority Data
Apr. 30, 2025 (CN) 202510570085.5

(51) Int. Cl. H10K 50/86; H10K 50/858; H10K 102/00

(52) U.S. Cl. CPC H10K 50/865; H10K 50/858; H10K 2102/351

(57) ABSTRACT

A light-emitting element includes a substrate, a plurality of light-shielding layers, a covering layer, and a plurality of bumps. The plurality of light-shielding layers are disposed at intervals on a first surface of the substrate, wherein each of the plurality of light-shielding layers includes a first anti-reflection layer, a metal layer, and a second anti-reflection layer, the first anti-reflection layer having a bottom surface disposed on the first surface of the substrate and including at least one first bonding layer and at least one first light-absorbing layer; the metal layer disposed on the first anti-reflection layer; the second anti-reflection layer disposed on the metal layer and including at least one second bonding layer and at least one second light-absorbing layer, wherein one of the at least one second bonding layer serves as a top layer of the second anti-reflection layer. The covering layer covers the first surface of the substrate and the plurality of light-shielding layers. The plurality of bumps are arranged on the covering layer, each pair of adjacent bumps among the plurality of bumps including an organic light-emitting unit.

### PRIORITY CLAIM AND CROSS-REFERENCE

This application claims the benefit of China patent application No. 202510570085.5, filed on Apr. 30, 2025, the entirety of which are incorporated by reference herein.

### BACKGROUND OF THE DISCLOSURE

### Field of the Disclosure

The present disclosure relates to a light-emitting element, and more particularly to an organic light-emitting element.

### Description of the Prior Art

Organic light-emitting displays have been widely used in most high-end electronic devices. However, due to the limitations of existing technology, the luminous efficiency and quality of light-emitting materials cannot be effectively controlled, resulting in the optical performance of the devices being below expectations.

### SUMMARY OF THE DISCLOSURE

In the present disclosure, a light-emitting element includes a substrate, a plurality of light-shielding layers, a covering layer, and a plurality of bumps. The plurality of light-shielding layers are disposed at intervals over a first surface of the substrate, wherein each of the plurality of light-shielding layers includes a first anti-reflection layer, a metal layer, and a second anti-reflection layer, the first anti-reflection layer having a bottom surface disposed over the first surface of the substrate and including at least one first bonding layer and at least one first light-absorbing layer; a metal layer disposed over the first anti-reflection layer; a second anti-reflection layer disposed over the metal layer and including at least one second bonding layer and at least one second light-absorbing layer, wherein one of the at least one second bonding layer serves as a top layer of the second anti-reflection layer. The covering layer covers the first surface of the substrate and the plurality of light-shielding layers. The plurality of bumps are arranged over the covering layer, each pair of adjacent bumps among the plurality of bumps including an organic light-emitting unit.

In the present disclosure, a method of manufacturing a light-emitting element includes: providing a substrate; forming a plurality of first anti-reflection layers over the substrate, including applying at least one layer of a bonding material and at least one layer of a light-absorbing material, wherein the plurality of first anti-reflection layers are separated from each other by a distance; forming a plurality of metal layers over the plurality of first anti-reflection layers; forming a plurality of second anti-reflection layers over the plurality of metal layers, including applying at least one layer of a bonding material and at least one layer of a light-absorbing material, wherein a top layer of the plurality of second anti-reflection layers is one of the at least one layer of the bonding material; applying a covering layer to cover top surfaces of the plurality of second anti-reflection layers, the substrate exposed between the plurality of first anti-reflection layers, and side surfaces of the plurality of first anti-reflection layers, the plurality of metal layers, and the plurality of second anti-reflection layers; and alternately disposing a plurality of organic light-emitting units and a plurality of bumps over the covering layer.

In some embodiments, a material included in the second bonding layer serving as the top layer of the second anti-reflection layer is identical to a material included in the covering layer.

In some embodiments, a material included in the first bonding layer is identical to a material included in the second bonding layer, and the materials included in both the first bonding layer and the second bonding layer are identical to a material included in the covering layer.

In some embodiments, an effective refractive index of the first light-absorbing layer is greater than an effective refractive index of the first bonding layer; and an effective refractive index of the second light-absorbing layer is greater than an effective refractive index of the second bonding layer.

In some embodiments, the first light-absorbing layer includes a metal oxide and the second light-absorbing layer includes a metal oxide.

In some embodiments, a thickness of the first anti-reflection layer is substantially identical to a thickness of the second anti-reflection layer.

In some embodiments, a ratio of a thickness of the first anti-reflection layer to a thickness of the metal layer is in a range of about 1:1 to about 3:1; and a ratio of a thickness of the second anti-reflection layer to a thickness of the metal layer is in a range of about 1:1 to about 3:1.

In some embodiments, positions of the plurality of light-shielding layers correspond one-to-one with positions of the plurality of bumps.

In some embodiments, a width of each of the plurality of light-shielding layers is greater than a width of each of the plurality of bumps.

In some embodiments, one of the at least one first bonding layer of the first anti-reflection layer serves as a bottom layer of the first anti-reflection layer and is in direct contact with the substrate, and one of the at least one first light-absorbing layer serves as a top layer of the first anti-reflection layer and is in direct contact with the metal layer.

In some embodiments, the bonding material is identical to a material for forming the covering layer.

In some embodiments, each of the plurality of first anti-reflection layers is formed by sequentially applying a layer of the bonding material, a layer of the light-absorbing material, a layer of the bonding material, and a layer of the light-absorbing material over the substrate; and each of the plurality of second anti-reflection layers is formed by sequentially applying a layer of the light-absorbing material, a layer of the bonding material, a layer of the light-absorbing material, and a layer of the bonding material over the metal layer.

In some embodiments, the plurality of first anti-reflection layers, the plurality of metal layers, and the plurality of second anti-reflection layers are formed by an evaporation process.

### BRIEF DESCRIPTION OF THE DRAWINGS

FIG. 1 is a top view illustrating an intermediate product of a light-emitting element.

FIG. 2 is a cross-sectional view along a line AA in FIG. 1.

FIG. 3 is a cross-sectional view illustrating a light-shielding layer.

FIG. 4 is a cross-sectional view illustrating a light-shielding layer.

FIG. 5 is a cross-sectional view illustrating a light-shielding layer.

FIG. 6 is a cross-sectional view illustrating a light-shielding layer.

FIG. 7 is a cross-sectional view illustrating a light-shielding layer.

FIG. 8 is a cross-sectional view illustrating a light-shielding layer.

FIG. 9A to FIG. 9J illustrate different stages of a manufacturing process of a light-emitting element according to an embodiment.

### DETAILED DESCRIPTION OF THE EMBODIMENTS

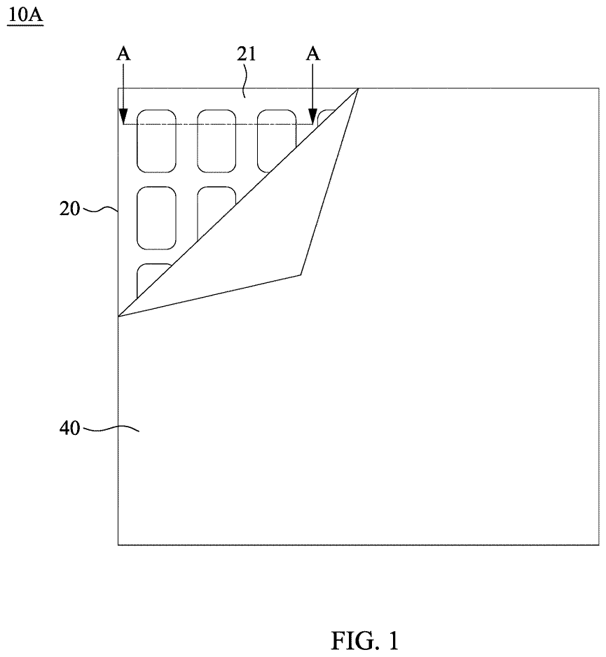

FIG. 1 is a top view illustrating an intermediate product of a light-emitting element 10A. The light-emitting element 10A comprises a light-emitting layer 20 and an overlying layer 40 located over the light-emitting layer 20. For the light-emitting layer 20, spacers 21 may be designed to provide an array of recesses for accommodating a light-emitting pixel array. In some embodiments, the spacers 21 may include a photosensitive material.

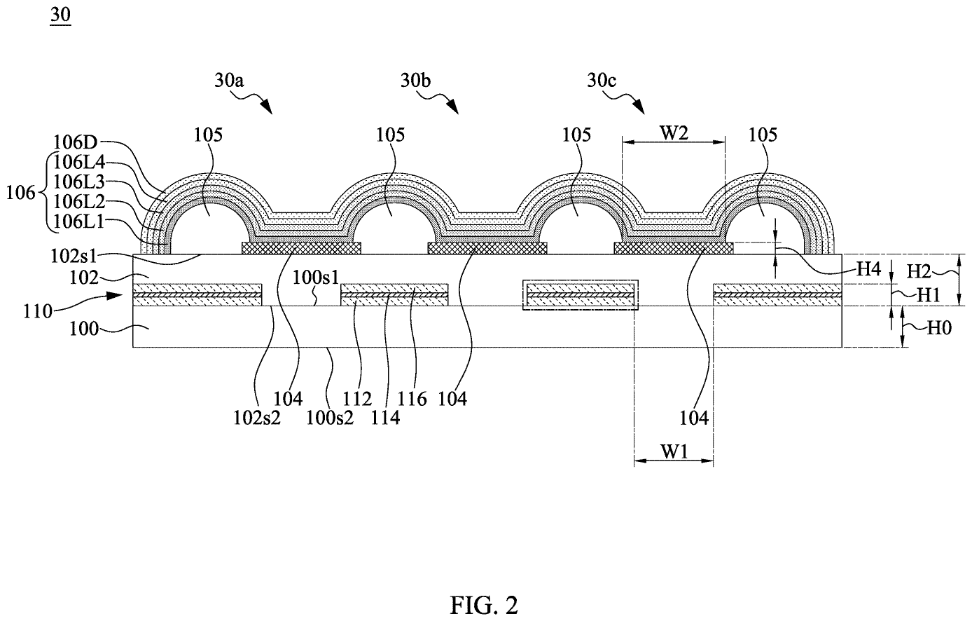

FIG. 2 is a cross-sectional view along a line AA in FIG. 1 and illustrates only a light-emitting region. For simplicity, the overlying layer 40 is omitted here. In some embodiments, the light-emitting element 30 comprises a substrate 100, a light-shielding layer 110, a covering layer 102, a first electrode 104, bumps 105, an organic light-emitting stack layer 106, a second electrode 106D, and a plurality of light-emitting units. In some embodiments, the organic light-emitting stack layer 106 comprises a carrier injection layer 106L1, a carrier transport layer 106L2, an organic emission layer 106L3, and an organic carrier transport layer 106L4. In some embodiments, the light-emitting element 30 comprises a first organic light-emitting unit 30a, a second organic light-emitting unit 30b, and a third organic light-emitting unit 30c.

In some embodiments, the substrate 100 may comprise a thin-film transistor (TFT) array. In some embodiments, the substrate 100 includes a base (not shown), a dielectric layer (not shown), and one or more circuits (not shown) disposed on or within the base. In some embodiments, the base is a transparent base, or at least partially transparent. In some embodiments, the base is a non-flexible base, and a material of the base may comprise glass, quartz, low-temperature poly-silicon (LTPS), or other suitable materials. In some embodiments, the base is a flexible base, and the material of the base may comprise transparent epoxy resin, polyimide, polyvinyl chloride, polymethyl methacrylate, or other suitable materials. The dielectric layer may be disposed on the base as needed. In some embodiments, the dielectric layer may comprise silicon oxide, silicon nitride, silicon oxynitride, or other suitable materials.

In some embodiments, the circuit may include complementary metal-oxide-semiconductor (CMOS) circuits, or several transistors and several capacitors adjacent to the transistors, where the transistors and capacitors are formed on the dielectric layer. In some embodiments, the transistors are thin-film transistors (TFTs). Each transistor comprises source/drain regions (including at least one source region and one drain region), a channel region between the source/drain regions, a gate electrode disposed over the channel region, and a gate insulator between the channel region and the gate electrode. The channel region of the transistor may be made of semiconductor material, such as silicon or other elements selected from Group IV or Groups III and V.

A plurality of light-shielding layers 110 are formed above the substrate 100. The plurality of light-shielding layers 110 are disposed at intervals on an upper surface 100s1 of the substrate 100 and directly contact the upper surface 100s1 of the substrate 100. The plurality of light-shielding layers 110 are separated from each other by a distance W1. A thickness H1 of the light-shielding layer 110 is less than a thickness H0 of the substrate 100. In some embodiments, a ratio of the thickness H1 of the light-shielding layer 110 to the thickness H0 of the substrate 100 is about 1:10 to about 1:1.5. In some embodiments, the ratio of the thickness H1 of the light-shielding layer 110 to the thickness H0 of the substrate 100 is about 1:8 to about 1:3. In some embodiments, the ratio of the thickness H1 of the light-shielding layer 110 to the thickness H0 of the substrate 100 is about 1:6 to about 1:4.

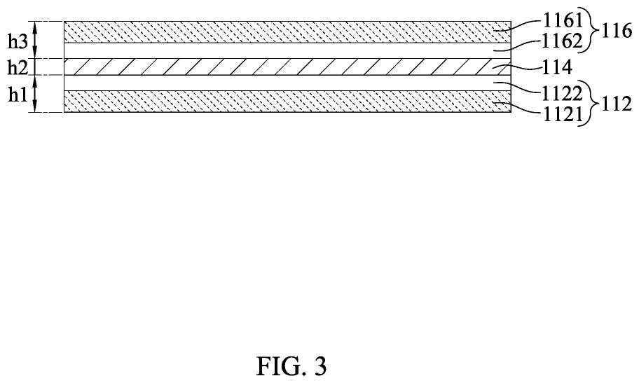

FIG. 3 is a cross-sectional view illustrating the light-shielding layer. In some embodiments, the plurality of light-shielding layers 110 can absorb more than 90% of visible light. In some embodiments, each light-shielding layer 110 comprises a first anti-reflection layer 112, a metal layer 114, and a second anti-reflection layer 116. A bottom surface of the first anti-reflection layer 112 is disposed on the upper surface 100s1 of the substrate 100 and comprises at least one first bonding layer 1121 and at least one first light-absorbing layer 1122. The metal layer 114 is disposed on the first anti-reflection layer 112. The second anti-reflection layer 116 is disposed on the metal layer 114 and comprises at least one second bonding layer 1161 and at least one second light-absorbing layer 1162, wherein at least one of the second bonding layers 1161 serves as a top layer of the second anti-reflection layer 116.

In some embodiments, a thickness h1 of the first anti-reflection layer 112 may be less than a thickness h2 of the metal layer 114; the thickness h1 of the first anti-reflection layer 112 may be substantially equal to the thickness h2 of the metal layer 114; the thickness h1 of the first anti-reflection layer 112 may be greater than the thickness h2 of the metal layer 114. In some embodiments, a thickness h3 of the second anti-reflection layer 116 may be less than the thickness h2 of the metal layer 114; the thickness h3 of the second anti-reflection layer 116 may be substantially equal to the thickness h2 of the metal layer 114. The thickness h3 of the second anti-reflection layer 116 may be greater than the thickness h2 of the metal layer 114. In some embodiments, the thickness h1 of the first anti-reflection layer 112 may be less than the thickness h3 of the second anti-reflection layer 116; the thickness h1 of the first anti-reflection layer 112 may be substantially equal to the thickness h3 of the second anti-reflection layer 116; the thickness h1 of the first anti-reflection layer 112 may be greater than the thickness h3 of the second anti-reflection layer 116. In some embodiments, a ratio of the thickness h1 of the first anti-reflection layer 112 to the thickness h2 of the metal layer 114 is about 3:1 to about 1:5. In some embodiments, the ratio of the thickness h1 of the first anti-reflection layer 112 to the thickness h2 of the metal layer 114 is about 1:1 to about 3:1. In some embodiments, a ratio of the thickness h3 of the second anti-reflection layer 116 to the thickness h2 of the metal layer 114 is about 3:1 to about 1:5. In some embodiments, the ratio of the thickness h3 of the second anti-reflection layer 116 to the thickness h2 of the metal layer 114 is about 1:1 to about 3:1. In some embodiments, a ratio of the thickness h1 of the first anti-reflection layer 112 to the thickness h3 of the second anti-reflection layer 116 is about 3:1 to about 1:3. In some embodiments, the ratio of the thickness h1 of the first anti-reflection layer 112 to the thickness h3 of the second anti-reflection layer 116 is about 2:1 to about 1:2. In some embodiments, the ratio of the thickness h1 of the first anti-reflection layer 112 to the thickness h3 of the second anti-reflection layer 116 may be substantially 1:1.

As shown in FIG. 3, the first anti-reflection layer 112 comprises a first bonding layer 1121 and a first light-absorbing layer 1122, wherein the first bonding layer 1121 is in direct contact with the upper surface 100s1 of the substrate 100, and the first light-absorbing layer 1122 is disposed on the first bonding layer 1121, so that the metal layer 114 is disposed on the first light-absorbing layer 1122. The second anti-reflection layer 116 comprises a second bonding layer 1161 and a second light-absorbing layer 1162, wherein the second light-absorbing layer 1162 is disposed on the metal layer 114 and in directly contact with the metal layer 114, and the second bonding layer 1161 is disposed on the second light-absorbing layer 1162 and in directly contact with the overlying covering layer 102. The thickness h1 of the first anti-reflection layer 112 is substantially equal to the thickness h3 of the second anti-reflection layer 116, the thickness h1 of the first anti-reflection layer 112 is greater than the thickness h2 of the metal layer 114, and the thickness h3 of the second anti-reflection layer 116 is greater than the thickness h2 of the metal layer 114.

In some embodiments, the first anti-reflection layer 112 may have a total thickness of about 1000 Å to about 5000 Å. In some embodiments, the first anti-reflection layer 112 may have a total thickness of about 1500 Å to about 4000 Å. In some embodiments, the first anti-reflection layer 112 may have a total thickness of about 2000 Å to about 3000 Å. In some embodiments, the metal layer 114 may have a thickness of about 500 Å to about 3000 Å. In some embodiments, the metal layer 114 may have a thickness of about 1000 Å to about 2000 Å. In some embodiments, the metal layer 114 may have a thickness of about 1200 Å to about 1600 Å. In some embodiments, the second anti-reflection layer 116 may have a total thickness of about 1000 Å to about 5000 Å. In some embodiments, the second anti-reflection layer 116 may have a total thickness of about 1500 Å to about 4000 Å. In some embodiments, the second anti-reflection layer 116 may have a total thickness of about 2000 Å to about 3000 Å.

In some embodiments, the first bonding layer 1121 may include a material with a low effective refractive index, such as silicon oxide (SiO₂). The first light-absorbing layer 1122 may include a material with a high effective refractive index, such as metal oxides (e.g., titanium oxide, TiO₂). In some embodiments, the material included in the second bonding layer 1161 may be the same as or different from the material included in the first bonding layer 1121, and the material included in the second light-absorbing layer 1162 may be the same as or different from the material included in the first light-absorbing layer 1122. The second bonding layer 1161 may include a material with a low effective refractive index, such as silicon oxide (SiO₂). The second light-absorbing layer 1162 may include a material with a high effective refractive index, such as metal oxides (e.g., titanium oxide, TiO₂). In some embodiments, the first anti-reflection layer 112 is transparent, the second anti-reflection layer 116 is transparent, and due to the presence of the metal layer, the light-shielding layer 110 still exhibits the color of the metal layer.

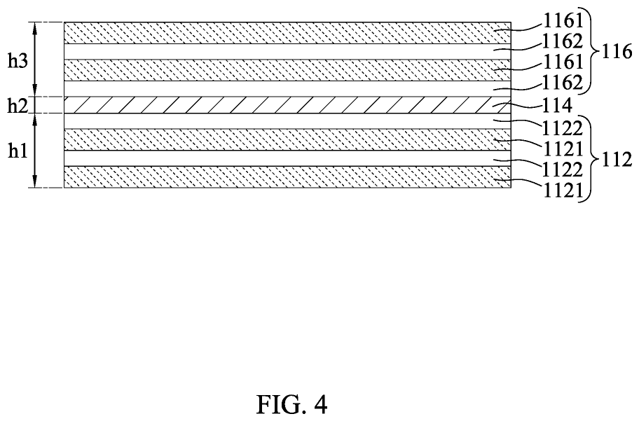

FIG. 4 illustrates a cross-sectional view of the light-shielding layer. In some embodiments, the first anti-reflection layer 112 comprises two first bonding layers 1121 and two first light-absorbing layers 1122 disposed at intervals, wherein one first bonding layer 1121 is disposed on the upper surface 100s1 of the substrate 100, followed sequentially by one first light-absorbing layer 1122, one first bonding layer 1121, and one first light-absorbing layer 1122. In some embodiments, more alternately disposed first bonding layers 1121 and first light-absorbing layers 1122 may be added to adjust suitable adhesion and light absorption effects. In some embodiments, the second anti-reflection layer 116 comprises two spaced second bonding layers 1161 and two second light-absorbing layers 1162 disposed at intervals, wherein one second light-absorbing layer 1162 is disposed on an upper surface of the metal layer 114, followed sequentially by one second bonding layer 1161, one second light-absorbing layer 1162, and one second bonding layer 1161, so that the top layer of the second anti-reflection layer 116 is a second bonding layer 1161. In some embodiments, more alternately disposed second bonding layers 1161 and second light-absorbing layers 1162 may be added to adjust suitable adhesion and light absorption effects. In some embodiments, the thickness h1 of the first anti-reflection layer 112 may be substantially equal to the thickness h3 of the second anti-reflection layer 116.

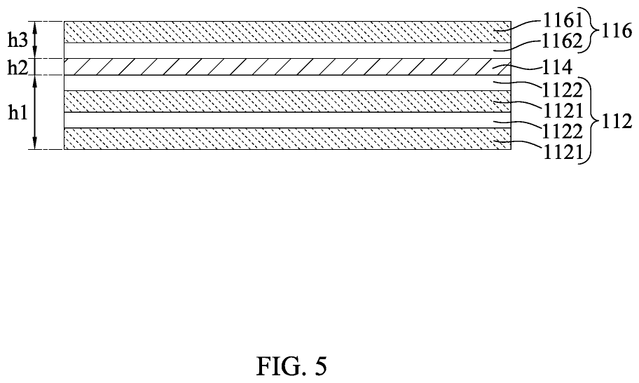

FIG. 5 illustrates a cross-sectional view of the light-shielding layer. In some embodiments, the thickness h1 of the first anti-reflection layer 112 may be greater than the thickness h3 of the second anti-reflection layer 116. In some embodiments, the first anti-reflection layer 112 comprises two first bonding layers 1121 and two first light-absorbing layers 1122 disposed at intervals, wherein one first bonding layer 1121 is disposed on the upper surface 100s1 of the substrate 100, followed sequentially by one first light-absorbing layer 1122, one first bonding layer 1121, and one first light-absorbing layer 1122. The second anti-reflection layer 116 comprises one second light-absorbing layer 1162 disposed on the upper surface of the metal layer 114 and one second bonding layer 1161 disposed on the second light-absorbing layer 1162, so that the top layer of the second anti-reflection layer 116 is a second bonding layer 1161.

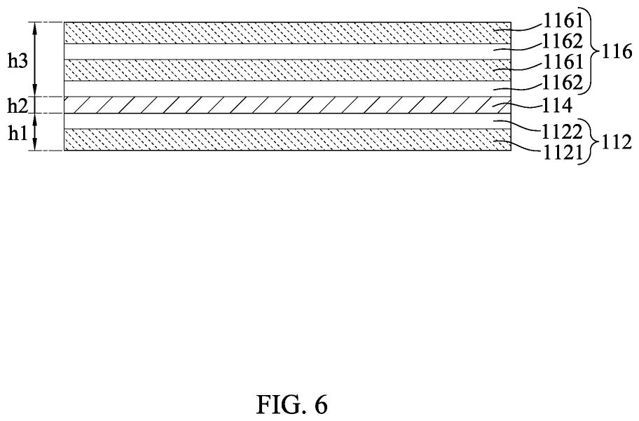

FIG. 6 illustrates a cross-sectional view of the light-shielding layer. In some embodiments, the thickness h1 of the first anti-reflection layer 112 may be less than the thickness h3 of the second anti-reflection layer 116. In some embodiments, the first anti-reflection layer 112 comprises one first bonding layer 1121 disposed on the upper surface 100s1 of the substrate 100 and one first light-absorbing layer 1122 disposed on the first bonding layer 1121. In some embodiments, the second anti-reflection layer 116 comprises two second bonding layers 1161 and two second light-absorbing layers 1162 disposed at intervals, wherein one second light-absorbing layer 1162 is disposed on the upper surface of the metal layer 114, followed sequentially by one second bonding layer 1161, one second light-absorbing layer 1162, and one second bonding layer 1161, so that the top layer of the second anti-reflection layer 116 is a second bonding layer 1161.

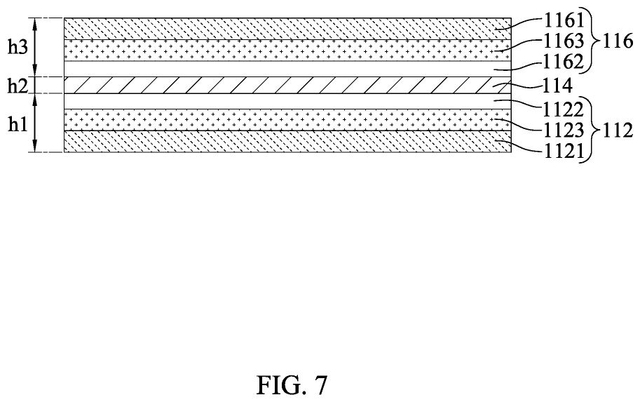

FIG. 7 illustrates a cross-sectional view of the light-shielding layer. In some embodiments, in the first anti-reflection layer 112, in addition to the first bonding layer 1121 and the first light-absorbing layer 1122, at least one other material layer may be further included to obtain different properties or performances, such as a structural reinforcement layer, an adhesive layer that increases the bonding stability between the first bonding layer 1121 and the first light-absorbing layer 1122, etc. In some embodiments, the first anti-reflection layer 112 comprises one first bonding layer 1121 disposed on the upper surface 100s1 of the substrate 100, one first additional material layer 1123 disposed on the first bonding layer 1121, and one first light-absorbing layer 1122 disposed on the first additional material layer 1123. In the second anti-reflection layer 116, in addition to the second bonding layer 1161 and the second light-absorbing layer 1162, at least one other material layer may be included to obtain different properties or performances, such as a structural reinforcement layer, an adhesive layer that increases the bonding stability between the second bonding layer 1161 and the second light-absorbing layer 1162, etc. In some embodiments, one second light-absorbing layer 1162 disposed on the upper surface of the metal layer 114, one second additional material layer 1163 disposed on the second light-absorbing layer 1162, and one second bonding layer 1161 disposed on the second additional material layer 1163 are included, so that the top layer of the second anti-reflection layer 116 is a second bonding layer 1161.

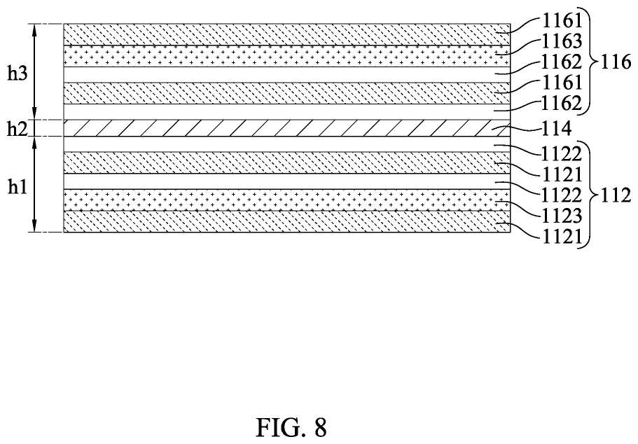

FIG. 8 illustrates a cross-sectional view of the light-shielding layer. In some embodiments, at least one first additional material layer 1123 may be disposed in any layer of the first anti-reflection layer 112, and at least one second additional material layer 1163 may be disposed in any layer of the second anti-reflection layer 116. In some embodiments, the first anti-reflection layer 112 comprises two first bonding layers 1121, two first light-absorbing layers 1122, and one first additional material layer 1123 disposed at intervals, wherein one first bonding layer 1121 is disposed on the upper surface 100s1 of the substrate 100, followed sequentially by one first additional material layer 1123, one first light-absorbing layer 1122, one first bonding layer 1121, and one first light-absorbing layer 1122. In some embodiments, the second anti-reflective layer 116 comprises two second bonding layers 1161, two second light-absorbing layers 1162, and one second additional material layer 1163 disposed at intervals, wherein one second light-absorbing layer 1162 is disposed on the upper surface of the metal layer 114, followed sequentially by one second bonding layer 1161, one second light-absorbing layer 1162, one second additional material layer 1163, and one second bonding layer 1161, so that the top layer of the second anti-reflective layer 116 is a second bonding layer 1161.

The covering layer 102 is formed over the substrate 100 and covers the plurality of light-shielding layers 110. The covering layer 102 is in contact with the upper surface 101s1 of the light-shielding layer 110. The covering layer 102 is in contact with two side surfaces 101s3 and 101s4 of the light-shielding layer 110. The covering layer 102 covers the upper surface 101s1 and the two side surfaces 101s3 and 101s4 of the light-shielding layer 110. The covering layer 102 is formed in gaps between the plurality of light-shielding layers 110. The thickness H2 of the covering layer 102 may be less than the thickness H0 of the substrate 100. The thickness H2 of the covering layer 102 may be substantially equal to the thickness H0 of the substrate 100. The thickness H2 of the covering layer 102 may be greater than the thickness H0 of the substrate 100. The thickness H2 of the covering layer 102 may be greater than the thickness H1 of the light-shielding layer 110. In some embodiments, a ratio of the thickness H1 of the light-shielding layer 110 to the thickness H2 of the covering layer 102 is about 1:10 to about 1:1.5. In some embodiments, the ratio of the thickness H1 of the light-shielding layer 110 to the thickness H0 of the substrate 100 is about 1:8 to about 1:3. In some embodiments, the ratio of the thickness H1 of the light-shielding layer 110 to the thickness H0 of the substrate 100 is about 1:6 to about 1:4. In some embodiments, a material included in the covering layer 102 may be the same as the material included in the first bonding layer 1121, such as silicon oxide, and the material included in the covering layer 102 may be the same as the material included in the second bonding layer 1161, such as silicon oxide, so that the bonding between the light-shielding layer 110 and the covering layer is firm. In some embodiments, the material included in the covering layer 102 may differ from the material included in the first bonding layer 1121, and the material included in the covering layer 102 may differ from the material included in the second bonding layer 1161, but they may be compatible with sufficient adhesion to ensure firm bonding between the light-shielding layer 110 and the covering layer.

A plurality of first electrodes 104 are formed above the covering layer 102. The plurality of first electrodes 104 is in contact with an upper surface 102s1 of the covering layer 102. The plurality of first electrodes 104 are separated from each other. The plurality of first electrodes 104 are in direct contact with the covering layer 102. The plurality of first electrodes 104 are electrically connected to the substrate 100.

A plurality of bumps 105 are formed on part of an upper surface of the first electrode 104. A surrounding area of the first electrode 104 is covered by the bumps 105. In some embodiments, an edge corner of the first electrode 104 is completely surrounded by the bumps 105. In some embodiments, sidewalls of the first electrode 104 are in full contact with the bumps 105. In some embodiments, two bumps 105 in a gap between two first electrodes 104 are separated from each other. The light-shielding layer 110 is electrically insulated from the first electrodes 104 disposed on the covering layer 102 through the covering layer 102. Positions of the plurality of bumps 105 may correspond one-to-one with positions of the plurality of light-shielding layers 110. In some embodiments, a width of each bump 105 may be substantially equal to a width of the corresponding light-shielding layer 110. In some embodiments, the width of each bump 105 may be less than the width of the corresponding light-shielding layer 110. In some embodiments, the width of each bump 105 may be greater than the width of the corresponding light-shielding layer 110. In some embodiments, edges of each bump 105 may align with edges of the corresponding light-shielding layer 110.

In some embodiments, a thickness H4 of the first electrode 104 is less than the thickness H1 of the light-shielding layer 110. The thickness H4 of the first electrode 104 may be substantially equal to the thickness H1 of the light-shielding layer 110. The thickness H4 of the first electrode 104 may be greater than the thickness H1 of the light-shielding layer 110. In some embodiments, a ratio of the thickness H1 of the light-shielding layer 110 to the thickness H4 of the first electrode 104 is about 10:1 to about 1:10. In some embodiments, the ratio of the thickness H1 of the light-shielding layer 110 to the thickness H0 of the substrate 100 is about 5:1 to about 1:5. In some embodiments, the ratio of the thickness H1 of the light-shielding layer 110 to the thickness H0 of the substrate 100 is about 3:1 to about 1:3.

The first electrode 104 may have a total thickness of about 1500 Å to about 2700 Å. In some embodiments, the first electrode 104 has a total thickness of about 1800 Å to about 2200 Å. In some embodiments, the first electrode 104 has a total thickness of about 2000 Å. The first electrode 104 may be a conductive layer. The first electrode 104 may include ITO, IZO, IGZO, AlCu alloy, AgMo alloy, ITO (or IZO or IGZO) with a thickness of about 50 Å to about 500 Å and a metal film (Ag, Al, Mg, Au) with a thickness of about 500 Å to about 2000 Å, and ITO (or IZO or IGZO) with a thickness of about 50 Å to about 1000 Å.

In some embodiments, the first electrode 104 is a composite structure. For example, the first electrode 104 comprises a conductive film and a transparent conductive film thereon. The conductive film is located between the transparent conductive film and the substrate 100. In some embodiments, the conductive film includes aluminum, gold, silver, copper, etc. In some embodiments, the transparent conductive film includes indium, tin, graphene, zinc, oxygen, etc. In some embodiments, the first electrode 104 comprises a transparent conductive thin film. In some embodiments, the first electrode 104 comprises ITO (indium tin oxide). In some embodiments, the first electrode 104 comprises IZO (indium zinc oxide). In some embodiments, the first electrode 104 comprises IGZO (indium gallium zinc oxide). In some embodiments, a roughness Ra of the transparent conductive film is less than 10 Å. A thickness of the conductive film may be between about 1500 Å and about 3000 Å. A thickness of the transparent conductive film may be between about 80 Å and about 1000 Å.

In some embodiments, the first electrode 104 comprises at least three different films. The conductive film (e.g., Al, Cu, Ag, Au, etc.) is sandwiched between two transparent conductive films. In some cases, one of the two transparent conductive films is ITO, with one side in contact with the substrate 100 and the other side in contact with the conductive film. In some cases, one of the two transparent conductive films is ITO, with one side in contact with the conductive film and the other side in contact with the bump 105 or the light-emitting material.

In some embodiments, each bump 105 has a curved surface that protrudes away from the substrate 100 and covers a peripheral area of the first electrode 104. The bumps 105 may have different shapes. In some embodiments, the bumps 105 have a curved surface. In some embodiments, the bumps 105 have a trapezoidal shape. In some embodiments, the bumps 105 have a rectangular shape. A pattern of the bumps 105 is designed according to the pixel arrangement, and the patterned bumps 105 may be referred to as a pixel defined layer (PDL). The bumps 105 are arranged above the covering layer 102. Each bump 105 fills the gap between two adjacent first electrodes 104. Each first electrode 104 is partially covered by the bump 105. The bumps 105 may include photosensitive material. In FIG. 2, an area of the light-shielding layer 110 in a lateral direction is larger than an area of each bump 105.

The bump 105 has an edge on an upper surface covering the first electrode 104. The light-shielding layer 110 has an edge near a center of the first electrode 104. The edge of the light-shielding layer 110 is not aligned with the edge of the bump 105. There is an offset between the edge of the bump 105 and the edge of the light-shielding layer 110. The offset may account for 10% or more of a width of the light-shielding layer 110. The offset may be 20% or more of a width of the light-shielding layer 110. The offset may be 30% or more of a width of the light-shielding layer 110. The offset may be 40% or more of the width of the light-shielding layer 110.

In some embodiments, a spacer 21 in FIG. 2 comprises several bumps 105 to define the light-emitting pixel pattern. A recessed area is located between two adjacent bumps 105 and provides space for accommodating the light-emitting pixels. Those skilled in the art should understand that from the cross-sectional view, the bumps 105 are shown as disconnected, but from the schematic top view of FIG. 2, they may be connected to each other via other parts of the spacer 21.

The light-emitting element 30 comprises a light-emitting array, which comprises a first organic light-emitting unit 30a, a second organic light-emitting unit 30b, and a third organic light-emitting unit 30c. The organic light-emitting units may also be referred to as light-emitting pixels in this application. In some embodiments, the light-emitting unit 30a comprises a first electrode 104, a carrier injection layer 106L1 over the bump 105 and the first electrode 104, a carrier transport layer 106L2 over the carrier injection layer 106L1, an organic emission layer 106L3 over a portion of the carrier transport layer 106L2, and an organic carrier transport layer 106L4 over the organic emission layer 106L3. The carrier injection layer 106L1, the carrier transport layer 106L2, the organic emission layer 106L3, and the organic carrier transport layer 106L4 may collectively be referred to as the organic light-emitting stack layer 106.

In some embodiments, the carrier injection layer 106L1 is arranged between the first electrode 104 and the carrier transport layer 106L2. The light-emitting unit 30a includes an organic material, which may be placed in any of the carrier transport layer, carrier injection layer, or organic emission layer of the light-emitting unit 30a depending on different embodiments. In some embodiments, this organic material has an absorption rate of greater than or equal to 50% for a specific wavelength; in some embodiments, an absorption rate of greater than or equal to 60% for a specific wavelength, in some embodiments, an absorption rate of greater than or equal to 70% for a specific wavelength, in some embodiments, an absorption rate of greater than or equal to 80% for a specific wavelength, in some embodiments, an absorption rate of greater than or equal to 90% for a specific wavelength, and in some embodiments, an absorption rate of greater than or equal to 95% for a specific wavelength. In some embodiments, the specific wavelength is not greater than 400 nm; in some embodiments, the specific wavelength is not greater than 350 nm; in some embodiments, the specific wavelength is not greater than 300 nm; in some embodiments, the specific wavelength is not greater than 250 nm; in some embodiments, the specific wavelength is not greater than 200 nm; in some embodiments, the specific wavelength is not greater than 150 nm; and in some embodiments, the specific wavelength is not greater than 100 nm.

In FIG. 2, a distance between the plurality of light-shielding layers 110 is W1, and a distance between two adjacent bumps 105 is W2. In some embodiments, the distance W2 between two adjacent bumps 105 is greater than the distance W1 between the plurality of light-shielding layers 110. In some embodiments, the distance W2 between two adjacent bumps 105 may define an area of an effective light-emitting region. Because the distance W1 between the plurality of light-shielding layers 110 is smaller than W2, the plurality of light-shielding layers 110 can control a light emitted from the first electrode 104, thereby improving the imaging effect of the pattern.

Furthermore, because the light-shielding layer 110 can shield ambient light traveling upward from the substrate 100, it can reduce optical crosstalk between the ambient light and the light emitted from the light-emitting unit 30a. Alternatively, because the light-shielding layer 110 can absorb more than 90% of the ambient light traveling upward from the substrate 100, it can reduce optical crosstalk between the ambient light and the light emitted by the light-emitting unit 30a. Since the top and bottom of the light-shielding layer 110 are both provided with anti-reflective layers, whether on the top or bottom surface of the light-shielding layer 110, it can be absorbed by the anti-reflective layer, avoiding affecting the performance of the light-emitting element 10, especially reducing the back-and-forth reflection of light emitted from the organic light-emitting units 30a, 30b, and 30c between the second electrode 106D and the light-shielding layer 110, thereby increasing imaging clarity. Moreover, the top layer of the light-shielding layer 110 is a second bonding layer 1161, which may include the same material as the overlying covering layer 102, thus enhancing the adhesion between the light-shielding layer 110 and the covering layer 102.

In some embodiments, the bump 105 has an absorption rate of greater than or equal to 50% at a specific wavelength; in some embodiments, the bump 105 has an absorption rate of greater than or equal to 60% at a specific wavelength; in some embodiments, the bump 105 has an absorption rate of greater than or equal to 70% at a specific wavelength; in some embodiments, the bump 105 has an absorption rate of greater than or equal to 80% at a specific wavelength; in some embodiments, the bump 105 has an absorption rate of greater than or equal to 90% at a specific wavelength; and in some embodiments, the bump 105 has an absorption rate of greater than or equal to 95% at a specific wavelength. In some embodiments, the specific wavelength is not greater than 400 nm; in some embodiments, the specific wavelength is not greater than 350 nm; in some embodiments, the specific wavelength is not greater than 300 nm; in some embodiments, the specific wavelength is not greater than 250 nm; in some embodiments, the specific wavelength is not greater than 200 nm; in some embodiments, the specific wavelength is not greater than 150 nm; and in some embodiments, the specific wavelength is not greater than 100 nm.

The carrier injection layer 106L1 is disposed on exposed surfaces of the first electrodes 104, the bumps 105, and the covering layer 102. The carrier injection layer 106L1 continuously covers the exposed surfaces of the first electrodes 104 and the bumps 105. In some embodiments, the exposed surface of each first electrode 104 is configured as an effective light-emitting region for a light-emitting unit 30a. Optionally, the carrier injection layer 106L1 is in contact with the bump 105. In some embodiments, the carrier injection layer 106L1 is in contact with the first electrode 104. In some embodiments, the carrier injection layer 106L1 is an organic material. In some embodiments, the carrier injection layer 106L1 is configured to perform hole injection. In some embodiments, the carrier injection layer 106L1 is a hole injection layer. In some embodiments, the carrier injection layer 106L1 may have a thickness of about 80 Å to about 500 Å.

The carrier transport layer 106L2 is disposed on the exposed surfaces of the first electrodes 104, the bumps 105, and the covering layer 102. The carrier transport layer 106L2 is disposed over the carrier injection layer 106L1 and completely covers the carrier injection layer 106L1. The carrier injection layer 106L1 is disposed below the carrier transport layer 106L2. The carrier transport layer 106L2 continuously covers the carrier injection layer 106L1. The carrier transport layer 106L2 covers the plurality of bumps 105 and the plurality of first electrodes 104. Optionally, the carrier transport layer 106L2 is in contact with the carrier injection layer 106L1. In some embodiments, the carrier transport layer 106L2 is an organic material. In some embodiments, the carrier transport layer 106L2 is configured to perform hole transport. In some embodiments, the carrier transport layer 106L2 is a first hole transport layer. In some embodiments, the carrier injection layer 106L1 may have a thickness of about 80 Å to about 500 Å.

The organic emission layer 106L3 is disposed on the exposed surfaces of the first electrodes 104, the bumps 105, and the covering layer 102. The organic emission layer 106L3 is disposed over the carrier transport layer 106L2 and completely covers the carrier transport layer 106L2. The carrier transport layer 106L2 is disposed below the organic emission layer 106L3. The organic emission layer 106L3 continuously covers the carrier transport layer 106L2. The organic emission layer 106L3 covers the plurality of bumps 105 and the plurality of first electrodes 104. Optionally, the organic emission layer 106L3 is in contact with the carrier transport layer 106L2. The organic emission layer 106L3 is configured to emit a first color.

In some embodiments, the organic emission layer 106L3 has an absorption rate of greater than or equal to 50% for a specific wavelength; in some embodiments, the organic emission layer 106L3 has an absorption rate of greater than or equal to 60% for a specific wavelength; in some embodiments, the organic emission layer 106L3 has an absorption rate of greater than or equal to 70% for a specific wavelength; in some embodiments, the organic emission layer 106L3 has an absorption rate of greater than or equal to 80% for a specific wavelength; in some embodiments, the organic emission layer 106L3 has an absorption rate of greater than or equal to 90% for a specific wavelength; in some embodiments, the organic emission layer 106L3 has an absorption rate of greater than or equal to 95% for a specific wavelength. In some embodiments, the specific wavelength is not greater than 400 nm; in some embodiments, the specific wavelength is not greater than 350 nm; in some embodiments, the specific wavelength is not greater than 300 nm; in some embodiments, the specific wavelength is not greater than 250 nm; in some embodiments, the specific wavelength is not greater than 200 nm; in some embodiments, the specific wavelength is not greater than 150 nm; in some embodiments, the specific wavelength is not greater than 100 nm.

In some embodiments, at least one of the carrier transport layer 106L2 and the organic emission layer 106L3 includes an organic material. The organic material may comprise a molecular structure having a resonance structure. The organic material may be selected from a group consisting of spiro-triarylamine, bis-triarylamine, and a combination thereof. In some embodiments, at least one of the carrier transport layer 106L2 and the organic emission layer 106L3 comprises spiro-triarylamine. In some embodiments, at least one of the carrier transport layer 106L2 and the organic emission layer 106L3 comprises bis-triarylamine.

The organic carrier transport layer 106L4 is disposed on the exposed surfaces of the first electrodes 104, the bumps 105, and the covering layer 102. The organic carrier transport layer 106L4 is disposed over and completely covers the organic emission layer 106L3. The organic emission layer 106L3 is disposed beneath the organic carrier transport layer 106L4. The organic carrier transport layer 106L4 continuously covers the organic emission layer 106L3. The organic carrier transport layer 106L4 covers the plurality of bumps 105 and the plurality of first electrodes 104. Optionally, the organic carrier transport layer 106L4 is in contact with the organic emission layer 106L3.

The second electrode 106D is disposed on the exposed surfaces of the first electrodes 104, the bumps 105, and the covering layer 102. The second electrode 106D is located over and completely covers the organic carrier transport layer 106L4. In some cases, the second electrode 106D is patterned to cover only the effective light-emitting regions of each light-emitting pixel. In some cases, the second electrode 106D is in contact with the organic carrier transport layer 106L4.

The second electrode 106D may have a thickness of about 80 Å to about 500 Å. In some embodiments, the second electrode 106D may have a thickness of about 80 Å to about 150 Å. In some embodiments, the second electrode 106D may have a thickness of about 150 Å to about 200 Å. In some embodiments, the second electrode 106D may have a thickness of about 200 Å to about 300 Å. In some embodiments, the second electrode 106D may have a thickness of about 300 Å to about 400 Å. In some embodiments, the second electrode 106D may have a thickness of about 400 Å to about 500 Å.

In some embodiments, the second electrode 106D may be a cathode. The second electrode 106D may be made of metal materials, such as Ag, Mg, etc. In some embodiments, the second electrode 106D comprises ITO (indium tin oxide) or IZO (indium zinc oxide). In some embodiments, the second electrode 106D is a composite structure. For example, the second electrode 106D comprises a conductive film and a transparent conductive film thereon. The conductive film is located between the transparent conductive film and the organic carrier transport layer 106L4. In some embodiments, the conductive film includes aluminum, gold, silver, copper, magnesium, molybdenum, etc. In some embodiments, the transparent conductive film includes indium, tin, graphene, zinc, oxygen, etc. In some embodiments, the transparent conductive film is ITO (indium tin oxide). In some embodiments, the transparent conductive film is IZO (indium zinc oxide). In some embodiments, the transparent conductive film is located between the conductive film and the organic carrier transport layer 106L4.

A plurality of light-emitting units are separated by bumps 105. These light-emitting units comprise a first light-emitting unit 30a, a second light-emitting unit 30b, and a third light-emitting unit 30c. In some embodiments, the first light-emitting unit 30a, the second light-emitting unit 30b, and the third light-emitting unit 30c are adjacent to each other. In some embodiments, the second light-emitting unit 30b and the third light-emitting unit 30c have a structure similar to that of the first light-emitting unit 30a. Furthermore, although the first light-emitting unit 30a, the second light-emitting unit 30b, and the third light-emitting unit 30c are illustrated as having similar features, this is merely exemplary and not intended to limit these embodiments. The first light-emitting unit 30a, the second light-emitting unit 30b, and the third light-emitting unit 30c may have similar or different structures to meet desired functional requirements.

The first light-emitting unit 30a, the second light-emitting unit 30b, and the third light-emitting unit 30c may differ from each other at least in the thickness of the organic light-emitting stack layers. In some embodiments, the first light-emitting unit 30a emits green light, the second light-emitting unit 30b emits red light, and the third light-emitting unit 30c emits blue light.

In some embodiments, the light-emitting units 30a, 30b, and 30c are configured to be divided into at least three different groups, wherein each group emits a color different from the colors emitted by the other groups. The thickness of each organic light-emitting stack layer may be related to the color displayed by the corresponding light-emitting unit 30a, 30b, or 30c. In some embodiments, compared to other light-emitting units configured to emit different colors, the first light-emitting unit 30a emits green light, and the organic light-emitting stack layer in the first light-emitting unit 30a may have the minimum thickness. In some embodiments, compared to other light-emitting units configured to emit different colors, the second light-emitting unit 30b emits red light, and the thickness of the organic light-emitting stack layer in the second light-emitting unit 30b may be between the thicknesses of the organic light-emitting stack layer in the first light-emitting unit 30a and the thicknesses of the organic light-emitting stack layer in the third light-emitting unit 30c. In some embodiments, compared to other light-emitting units configured to emit different colors, the third light-emitting unit 30c emits blue light, and the organic light-emitting stack layer in the third light-emitting unit 30c may have the maximum thickness. The organic light-emitting stack layers of the first light-emitting unit 30a, the second light-emitting unit 30b, and the third light-emitting unit 30c may be formed by various processes such as vapor deposition, liquid jetting, or inkjet printing.

In some embodiments, the first, second, and third light-emitting units 30a, 30b, and 30c may differ from each other at least in the thickness differences of the carrier transport layers of the first, second, and third light-emitting units 30a, 30b, and 30c.

In some embodiments, the light-emitting units 30a, 30b, and 30c are configured to be divided into at least three different groups, wherein each group emits a color different from the colors emitted by the other groups. The thickness of the carrier transport layer may be related to the color displayed by the corresponding light-emitting unit 30a. In some embodiments, compared to other light-emitting units configured to emit different colors, the first light-emitting unit 30a emits green light, and the carrier transport layer in the first light-emitting unit 30a may have the minimum thickness. In some embodiments, compared to other light-emitting units configured to emit different colors, the second light-emitting unit 30b emits red light, and the thickness of the carrier transport layer in the second light-emitting unit 30b may be between the thickness of the carrier transport layer in the first light-emitting unit 30a and the thickness of the carrier transport layer in the third light-emitting unit 30c. In some embodiments, compared to other light-emitting units configured to emit different colors, the third light-emitting unit 30c emits blue light, and the carrier transport layer in the third light-emitting unit 30c may have the maximum thickness.

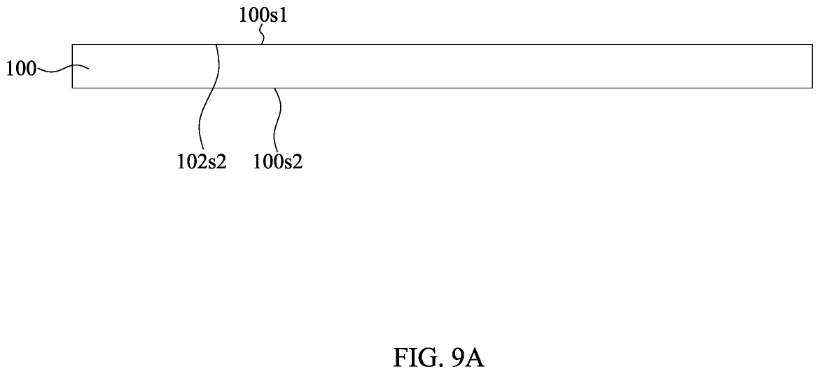

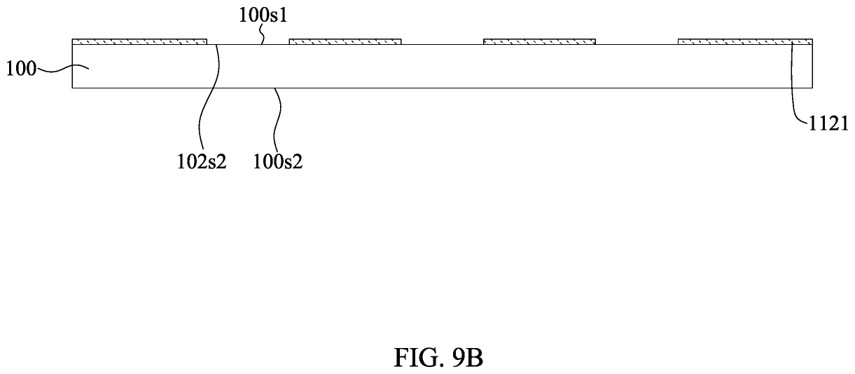

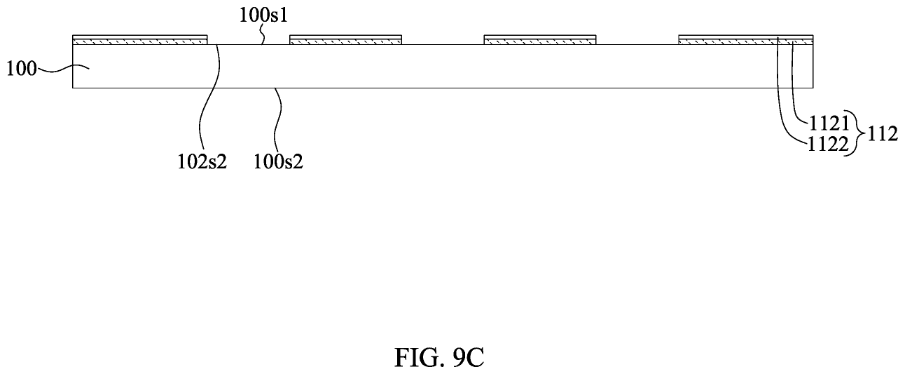

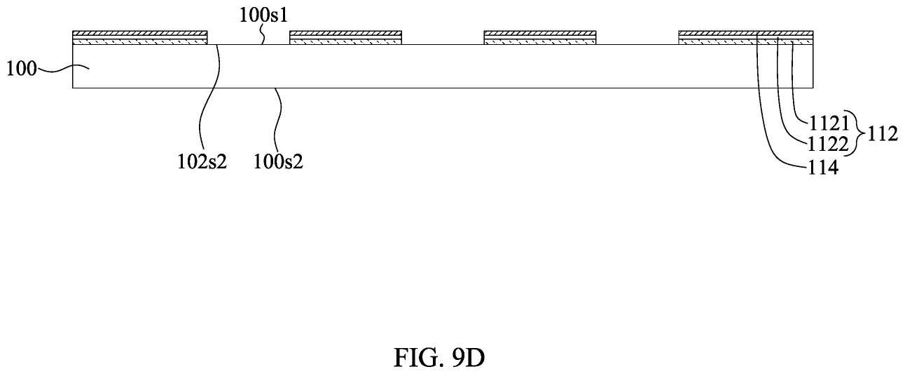

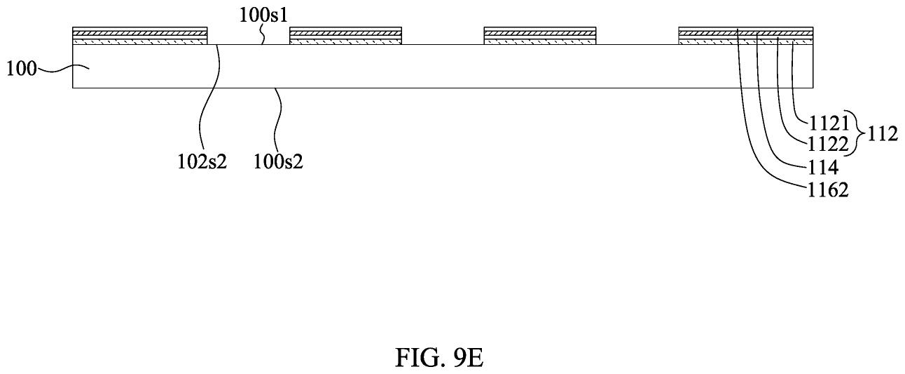

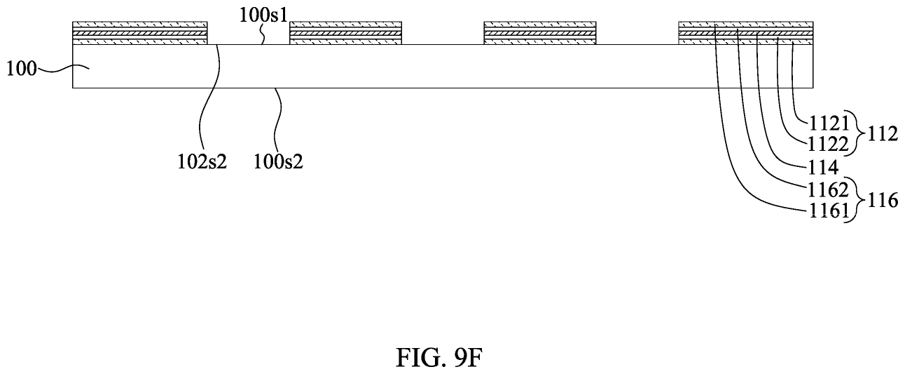

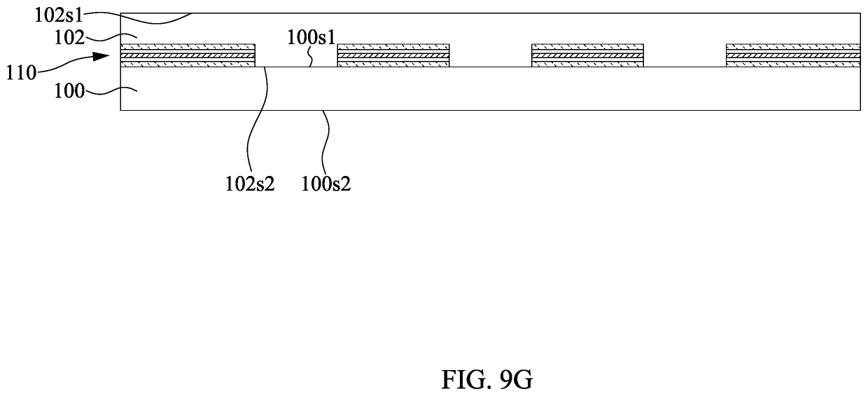

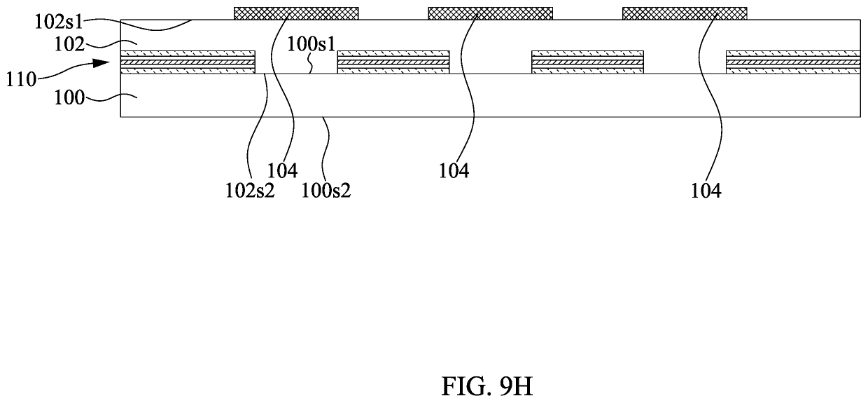

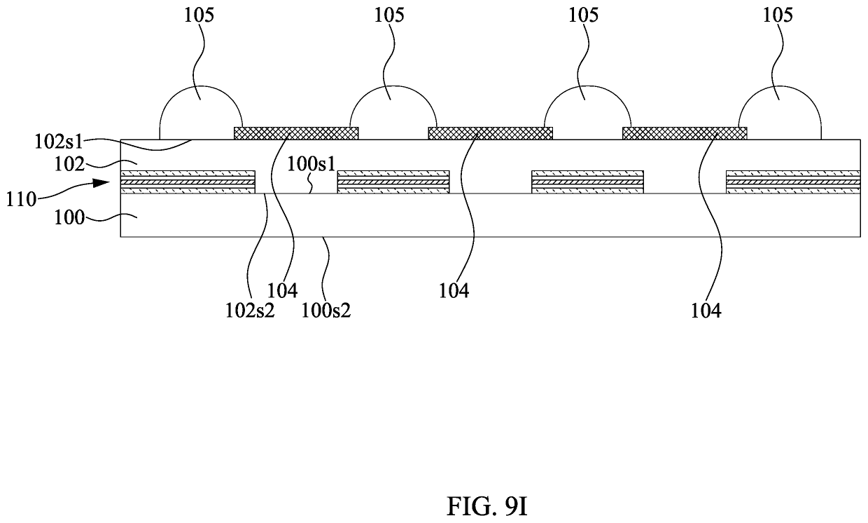

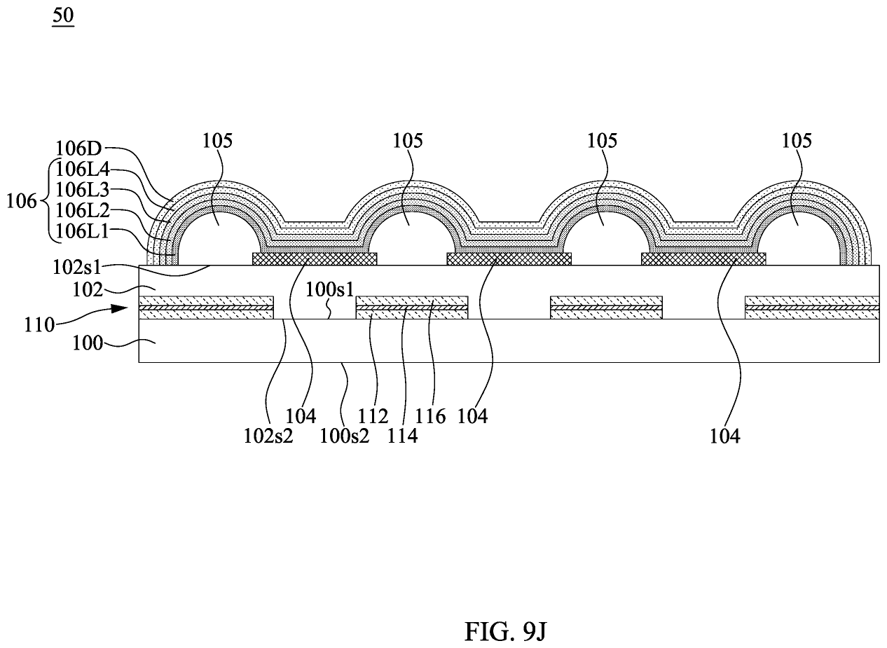

FIGS. 9A to 9J illustrate different stages of a manufacturing process of the light-emitting element 50 according to an embodiment.

In FIG. 9A, a substrate 100 is provided, which has an upper surface 100s1 and a lower surface 100s2.

In FIGS. 9B to 9F, a plurality of light-shielding layers 110 are disposed on the substrate 100. Each light-shielding layer 110 is configured on the same side of the substrate. Each light-shielding layer 110 is in contact with the upper surface 100s1 of the substrate 100. The light-shielding layers 110 are separated from each other. The lower surface 101s2 of the light-shielding layer 110 is in direct contact with the upper surface 100s1 of the substrate 100.

Disposing the plurality of light-shielding layers 110 comprises arranging a plurality of bonding materials at intervals to form a first bonding layer 1121 (as shown in FIG. 9B), then applying a light-absorbing material on each first bonding layer 1121 to form a first light-absorbing layer 1122 (as shown in FIG. 9C). The first bonding layer 1121 and the first light-absorbing layer 1122 form the first anti-reflection layer 112, and more first bonding layers 1121 and first light-absorbing layers 1122 may be alternately arranged in layers.

Disposing the plurality of light-shielding layers 110 further comprises forming a metal layer 114 on the first light-absorbing layer 1122 (as shown in FIG. 9D), then sequentially applying a light-absorbing material on the metal layer 114 to form a second light-absorbing layer 1162 (as shown in FIG. 9E), and applying bonding material to form a second bonding layer 1161 (as shown in FIG. 9F). The second light-absorbing layer 1162 and the second bonding layer 1161 form the second anti-reflection layer 114, and more second light-absorbing layers 1162 and second bonding layers 1161 may be alternately arranged in layers, provided that the top layer of the second anti-reflection layer 116 is the second bonding layer 1161.

The application of the first bonding layer 1121, the first light-absorbing layer 1122, metal layer 114, the second light-absorbing layer 1162, and the second bonding layer 1161 may be formed by any one of vapor deposition, sputtering, atomic layer deposition, thermal evaporation, coating, or spraying.

As shown in FIG. 9G, a covering layer 102 is disposed on each light-shielding layers 110. The covering layer 102 surrounds the upper surface 101s1 and two side surfaces 101s3 and 101s4 of each of the plurality of light-shielding layers 110. The covering layer 102 is in contact with the substrate 100. The covering layer 102 is formed over the plurality of light-shielding layers 110 by one of chemical vapor deposition (CVD), physical vapor deposition (PVD), or spin-on glass (SOG) spin coating. The material included in the covering layer 102 may be the same as the material included in the second bonding layer 1161.

As shown in FIG. 9H, a plurality of first electrodes 104 are disposed on the covering layer 102. Each first electrode 104 is arranged to be electrically connected to the substrate 100. Each first electrode 104 is in direct contact with the upper surface 102s1 of the covering layer 102. The array pattern of the first electrodes 104 is designed considering the arrangement of pixels.

As shown in FIG. 9I, a plurality of bumps 105 are disposed on the covering layer 102. Positions of the plurality of bumps 105 correspond one-to-one with positions of the plurality of light-shielding layers 110. In some embodiments, a width of each bump 105 may substantially correspond to a width of the corresponding light-shielding layer 110. In some embodiments, the width of each bump 105 may be smaller than the width of the corresponding light-shielding layer 110. In some embodiments, the width of each bump 105 may be larger than the width of the corresponding light-shielding layer 110. In some embodiments, an edge of each bump 105 may be aligned with an edge of the corresponding light-shielding layer 110. Each bump 105 is formed on a portion of the upper surface of the first electrode 104 and covers one side surface of the first electrode 104. The bumps 105 partially cover each first electrode 104. The bumps 105 may be formed in different shapes. In some embodiments, the bumps 105 have a curved surface. In some embodiments, the bumps 105 have a trapezoidal shape. After forming the bumps 105, a cleaning operation is performed to clean the exposed surfaces of the first electrodes 104 and the bumps 105. In one embodiment, during the cleaning operation, deionized water is heated to a temperature between 30 °C and 80 °C. After the temperature of the deionized water is raised to a predetermined temperature, the deionized water is directed onto the exposed surfaces of the first electrodes 104 and the bumps 105.

In some embodiments, ultrasonic waves are used during the cleaning operation. The ultrasonic waves are introduced into a cleaning agent (for example, water or isopropyl alcohol (IPA), etc.). In some embodiments, carbon dioxide is introduced into the cleaning agent. After the cleaning operation, the cleaning agent is removed from the exposed surfaces by a heating operation. During the heating operation, the substrate 100 and the bumps 105 may be heated to a temperature between 80 °C and 110 °C. In some examples, compressed air is directed onto the exposed surfaces to help remove residues of the cleaning agent while heating. After the heating operation, the exposed surfaces may be treated with O₂, N₂, or Ar plasma. The plasma is used to roughen the exposed surfaces. In some embodiments, ozone is used to adjust the surface condition of the exposed surfaces.

As shown in FIG. 9J, a carrier injection layer 106L1 is disposed over the bumps 105, portions of the exposed surfaces of the covering layer 102, and the exposed surfaces of the first electrodes 104. The carrier injection layer 106L1 continuously lines along the exposed surfaces. More specifically, the exposed surfaces of each first electrode 104 are configured as the effective light-emitting area of a light-emitting unit (i.e., a pixel). In this embodiment, all light-emitting units use the carrier injection layer 106L1. In some embodiments, the carrier injection layer 106L1 is used for hole injection. In some embodiments, the carrier injection layer 106L1 is used for electron injection. The carrier injection layer 106L1 continuously covers the plurality of bumps 105 and the exposed surfaces of the first electrodes 104. Optionally, the carrier injection layer 106L1 is in contact with the bumps 105. In one embodiment, the carrier injection layer 106L1 is in contact with the first electrodes 104. In some embodiments, the carrier injection layer 106L1 is organic.

A carrier transport layer 106L2 is disposed over the bumps 105, portions of the exposed surface of the covering layer 102, and the exposed surface of the first electrode 104. The carrier injection layer 106L1 is disposed beneath the carrier transport layer 106L2. The carrier transport layer 106L2 continuously lines along the carrier injection layer 106L1. In this embodiment, all the light-emitting units use the carrier transport layer 106L2. In some embodiments, the carrier transport layer 106L2 is used for hole injection. In some embodiments, the carrier transport layer 106L2 is used for electron injection. The carrier transport layer 106L2 continuously covers the plurality of bumps 105 and the first electrode 104. Optionally, the carrier transport layer 106L2 is in contact with the carrier injection layer 106L1. In some embodiments, the carrier transport layer 106L2 is organic. An organic emission layer 106L3 is disposed over the bumps 105, portions of the exposed surfaces of the covering layer 102, and the exposed surface of the first electrode 104. The organic emission layer 106L3 covers the carrier transport layer 106L2. The organic emission layer 106L3 completely covers the exposed carrier transport layer 106L2. The organic emission layer 106L3 is configured to emit a first color.

As shown in FIG. 9J, an organic carrier transport layer 106L4 is disposed on the organic emission layer 106L3. The organic carrier transport layer 106L4 may be a hole or electron transport layer. In some embodiments, the organic carrier transport layer 106L4 and the carrier transport layer 106L2 are each configured with opposite valence states. In some embodiments, a second electrode 106D is disposed on the organic carrier transport layer 106L4. The second electrode 106D covers the organic carrier transport layer 106L4. The second electrode 106D may be a metal material, such as Ag, Mg, etc. In some embodiments, the second electrode 106D includes ITO (indium tin oxide) or IZO (indium zinc oxide). In some embodiments, viewed from a cross-sectional view, each light-emitting unit (i.e., pixel) has an independent second electrode 106D.

The operations shown in FIGS. 9A-9J may be repeatedly performed to form light-emitting units of different colors.

This application allows the pattern to be adjusted into the desired shape according to actual needs.

The foregoing content outlines features of some embodiments, so those skilled in the art can better understand various aspects of the present disclosure. Those skilled in the art should understand that the present disclosure can be easily used as a basis to design or modify other processes and structures to achieve the same purposes and/or advantages as the embodiments described in this application. Those skilled in the art should also understand that such equivalent structures do not depart from the spirit and scope of the present disclosure, and that various changes, substitutions, and replacements can be made without departing from the spirit and scope of the present disclosure.

What is claimed is:

1. A light-emitting element, comprising:
a substrate;
a plurality of light-shielding layers disposed at intervals over a first surface of the substrate, wherein each of the plurality of light-shielding layers comprises:
a first anti-reflection layer having a bottom surface disposed over the first surface of the substrate and comprising at least one first bonding layer and at least one first light-absorbing layer;
a metal layer disposed over the first anti-reflection layer; and
a second anti-reflection layer disposed over the metal layer and comprising at least one second bonding layer and at least one second light-absorbing layer, wherein one of the at least one second bonding layer serves as a top layer of the second anti-reflection layer;
a covering layer covering the first surface of the substrate and the plurality of light-shielding layers; and
a plurality of bumps arranged over the covering layer, each pair of adjacent bumps among the plurality of bumps comprising an organic light-emitting unit.

2. The light-emitting element of claim 1, wherein a material included in the second bonding layer serving as the top layer of the second anti-reflection layer is identical to a material included in the covering layer.

3. The light-emitting element of claim 1, wherein a material included in the first bonding layer is identical to a material included in the second bonding layer, and the materials included in both the first bonding layer and the second bonding layer are identical to a material included in the covering layer.

4. The light-emitting element of claim 1, wherein an effective refractive index of the first light-absorbing layer is greater than an effective refractive index of the first bonding layer; and an effective refractive index of the second light-absorbing layer is greater than an effective refractive index of the second bonding layer.

5. The light-emitting element of claim 1, wherein the first light-absorbing layer includes a metal oxide and the second light-absorbing layer includes a metal oxide.

6. The light-emitting element of claim 1, wherein a thickness of the first anti-reflection layer is substantially identical to a thickness of the second anti-reflection layer.

7. The light-emitting element of claim 1, wherein a ratio of a thickness of the first anti-reflection layer to a thickness of the metal layer is in a range of about 1:1 to about 3:1; and a ratio of a thickness of the second anti-reflection layer to a thickness of the metal layer is in a range of about 1:1 to about 3:1.

8. The light-emitting element of claim 1, wherein positions of the plurality of light-shielding layers correspond one-to-one with positions of the plurality of bumps.

9. The light-emitting element of claim 1, wherein a width of each of the plurality of light-shielding layers is greater than a width of each of the plurality of bumps.

10. The light-emitting element of claim 1, wherein one of the at least one first bonding layer of the first anti-reflection layer serves as a bottom layer of the first anti-reflection layer and is in direct contact with the substrate, and one of the at least one first light-absorbing layer serves as a top layer of the first anti-reflection layer and is in direct contact with the metal layer.

11. A method of manufacturing a light-emitting element, comprising:
providing a substrate;
forming a plurality of first anti-reflection layers over the substrate, comprising applying at least one layer of a bonding material and at least one layer of a light-absorbing material, wherein the plurality of first anti-reflection layers are separated from each other by a distance;
forming a plurality of metal layers over the plurality of first anti-reflection layers;
forming a plurality of second anti-reflection layers over the plurality of metal layers, comprising applying at least one layer of a bonding material and at least one layer of a light-absorbing material, wherein a top layer of the plurality of second anti-reflection layers is one of the at least one layer of the bonding material;
applying a covering layer to cover top surfaces of the plurality of second anti-reflection layers, a portion of the substrate exposed between the plurality of first anti-reflection layers, and side surfaces of the plurality of first anti-reflection layers, the plurality of metal layers, and the plurality of second anti-reflection layers; and
alternately disposing a plurality of organic light-emitting units and a plurality of bumps over the covering layer.

12. The method of claim 11, wherein the bonding material is identical to a material for forming the covering layer.

13. The method of claim 11, wherein the light-absorbing material is a metal oxide.

14. The method of claim 11, wherein
each of the plurality of first anti-reflection layers is formed by sequentially applying a layer of the bonding material, a layer of the light-absorbing material, a layer of the bonding material, and a layer of the light-absorbing material over the substrate; and
each of the plurality of second anti-reflection layers is formed by sequentially applying a layer of the light-absorbing material, a layer of the bonding material, a layer of the light-absorbing material, and a layer of the bonding material over the metal layer.

15. The method of claim 11, wherein the plurality of first anti-reflection layers, the plurality of metal layers, and the plurality of second anti-reflection layers are formed by an evaporation process.
